(19) United States
(12) Patent Application Publication
(10) Pub. No.: US 2022/0247409 A1
(43) Pub. Date: Aug. 4, 2022

(54) USER INTERFACE SYSTEM FOR CONTROLLING A VEHICLE OPERATION

(71) Applicant: MAGNA CLOSURES INC., Newmarket (CA)

(72) Inventors: Mirko Pribisic, North York (CA); Allan Corner, Aurora (CA)

(21) Appl. No.: 17/728,231

(22) Filed: Apr. 25, 2022

Related U.S. Application Data
(63) Continuation of application No. 16/006,926, filed on Jun. 13, 2018.
(60) Provisional application No. 62/519,927, filed on Jun. 15, 2017.

(51) Int. Cl. H03K 17/96; G06F 3/044

(52) U.S. Cl. CPC H03K 17/9622; G06F 3/0443; B60R 25/01; H03K 2217/960735; H03K 2217/960705; H03K 2217/960785

(57) ABSTRACT

A user interface system for controlling a vehicle operation including a printed circuit board (PCB) that has a front side and a back side. A top layer that is electrically conductive defines the front side of the PCB. A plurality of indicia are etched into the top layer. An applique overlies the front side of the PCB. At least one proximity sensor is integrated into the front side of the PCB for detecting user object adjacent to the associated indicia and outputting a corresponding detection signal. The PCB further includes a base layer under the top layer. The base layer is at least partially formed of an optically transparent material. At least one light emitting device is positioned on the back side of the PCB for illuminating the indicia. A controller unit is coupled to the at least one proximity sensor and the at least one light emitting device.

### CROSS-REFERENCE TO RELATED APPLICATIONS

This application is a continuation of U.S. patent application Ser. No. 16/006,926 filed on Jun. 13, 2018, which claims the benefit of U.S. Provisional Application No. 62/519,927 filed Jun. 15, 2017. The entire disclosure of each of the above applications is incorporated herein by reference.

### FIELD

The present disclosure relates generally to user interface system for controlling a vehicle operation. More particularly, to a user interface system having a printed circuit board with integrated proximity sensors.

### BACKGROUND

This section provides background information related to the present disclosure which is not necessarily prior art.

Many passenger vehicles and trucks are now equipped with user interface systems for controlling vehicle operations. Such user interface systems include keyless entry systems, which may stand alone or be used in combination with a traditional mechanical-type (e.g., key) entry system. In many instances, the keyless entry system includes a portable device, such as a key fob, having pushbuttons that can be manipulated to unlock/lock the vehicle doors as well as perform other functions (e.g., selective activation of alarms, headlights and/or the ignition system) through encoded RF signals transmitted to a vehicle-installed receiver. Typically, the signals supplied to the receiver are primarily used to control the selective locking and unlocking of a power-operated door latch mechanism.

Certain vehicles may be equipped with a vehicle-mounted keyless entry system. Typically, a touch device, such as a keypad, is mounted to the vehicle in close proximity to the door handle (e.g., on the door or the B-pillar) which enables an authorized user to enter a passcode consisting of a sequence of alpha or numerical codes. Upon verification of the passcode, an on-board controller unit controls operation of the power-operated door latch mechanism. The keypad may also be used to control other vehicle operational functions such as, for example, power release of the gas tank cover or the tailgate lift system following entry and verification of the correct passcode. Some keypads use pushbuttons and/or switches to enter the authentication code. One example of a touchless keyless entry keypad associated with a vehicle entry system is disclosed in U.S. Pat. No. 8,400,265 the entire disclosure of which is herein incorporated by reference. As disclosed in the '265 patent, a plurality of proximity sensors, such as capacitive sensors, are used to as the code input interfaces associated with the keypad.

A further example of a keyless entry keypad assembly is disclosed in FIG. 1. The keyless entry keypad assembly 10 includes a transparent applique 12 which acts as an outer protective cover for the assembly 10 and defines a touch surface 13, which may be touched by a user. A printed circuit board (PCB) 14 is disposed beneath the applique 12. The printed circuit board 14 includes a plurality of capacitive electrodes 16 for detecting touching of the applique 12 by a user. The capacitive electrodes 16 are electrically connected to a controller for processing the detections of touching the applique 12 to perform functions such as unlocking the doors of the vehicle. An optical mask 20 is disposed between the PCB 14 and the applique 12 and includes a plurality of indicia 22 for indicating the locations of the capacitive electrodes 16. As such, the combination of the applique 12, optical mask 20 and capacitive electrodes 16 provides for the keypad assembly 10. A back cover 23 is disposed behind the PCB 14 for securing the various components of the assembly 10 in place. One or more light sources 24 are connected to the PCB 14 for illuminating the indicia 22 to indicate the locations of the capacitive electrodes 16 to users. Operation of the keyless entry keypad assembly 10 is configured to permit selective access to a passenger compartment when a user enters an authorization code via the keypad assembly 10 by touching the applique 12 in the proximity of the desired indicia 22.

Thus, the assembly 10 of FIG. 1 juxtaposes various components next to each other. A known issue with such an arrangement is that the capacitive electrodes 16 are positioned relatively far away from the touch surface 13 on the applique 12 due to the stacked arrangement. More particularly, the optical mask 20 and spacers position the PCB 14 apart from the optical mask 20 to create distance between the capacitive electrodes 16 and touch surface 13 of the applique 12. This may cause decreased detection sensitivity and difficulty in seeing the indicia 22.

A second known keyless entry keypad assembly 110 is disclosed in FIG. 2. Similar to the first assembly 10 of FIG. 1, the second assembly 110 includes an applique 112 defining a touch surface 113, an optical mask 120, a PCB 114 including capacitive electrodes 116, and a back cover 123. In addition, the optical mask 120 includes carbonized traces 126 electrically connected to the capacitive electrodes 116 for reducing the effective distance between the capacitive electrodes 116 and the touch surface 113 of the applique 112. A spacer 128 is provided between the optical mask 120 and the PCB 114. Furthermore, an elastomeric connector 130 (e.g., a ZEBRA® elastomeric connector) electrically connects the PCB 114 to the carbonized traces 126.

Issues with the assembly 110 of FIG. 2 are that the additional electrical elements like the carbonized traces 126 and elastomeric connector 130 add complexity to the assembly 110 and thus make the assembly 110 more prone to disconnection and more expensive.

While such keyless entry keypad assemblies 10, 110 have found widespread applications in vehicle door systems (e.g., passenger doors, tailgates and closure doors), a need exists to continually advance the art and address known deficiencies associated with conventional keyless entry keypad assemblies 10, 110.

A need therefore exists for an improved system of keyless entry of passenger entry doors and closure members in motor vehicles and other devices. Accordingly, a solution that addresses, at least in part, the above-noted shortcomings and advances the art is desired.

### SUMMARY

This section provides a general summary of the present disclosure and is not intended to be interpreted as a comprehensive disclosure of its full scope or all of its features, aspects and objectives.

It is an aspect of the present disclosure to provide a user interface system for controlling a vehicle operation. The user interface system includes a printed circuit board (PCB) having a front side and a back side. The printed circuit board includes a top layer being electrically conductive and defining the front side of the printed circuit board. The top layer of the printed circuit board includes at least one indicia etched into the top layer. At least one proximity sensor is integrated into the front side of the printed circuit board and aligned with the at least one indicia for detecting a user object adjacent to the at least one indicia and outputting a corresponding detection signal. The printed circuit board further includes a base layer under the top layer. The base layer is at least partially formed of an optically transparent material and defining the back side of the printed circuit board. At least one light emitting device is disposed under the at least one indicia for selectively illuminating the optically transparent material of the base layer under the at least one indicia to illuminate the at least one indicia. A controller unit is coupled to the at least one proximity sensor and the at least one light emitting device and configured to process the detection signal for controlling the vehicle operation and control selective illumination of the at least one light emitting device.

According to yet another aspect of the disclosure, a reflector overlies the back side of the printed circuit board for reflecting light from the at least one light emitting device through the base layer of the printed circuit board and to the at least one indicia.

According to yet another aspect of the disclosure, a back cover supports and protects the reflector and the printed circuit board.

According to yet another aspect of the disclosure, a ground layer overlies the back side of the printed circuit board for reducing electromagnetic interference.

According to yet another aspect of the disclosure, the at least one light emitting device includes a plurality of light emitting devices and the at least one proximity sensor includes a plurality of proximity sensors. Each of the plurality of light emitting devices is associated with and aligned with one of the plurality of indicia.

According to yet another aspect of the disclosure, the system further includes an applique that is at least semi-transparent overlying the front side of the printed circuit board and defining a touch surface.

According to yet another aspect of the disclosure, the at least one light emitting device is a light emitting diode.

According to yet another aspect of the disclosure, the printed circuit board defines at least one light channel adjacent to the at least one lighting emitting device for channeling light from the at least one lighting emitting device through the printed circuit board.

According to yet another aspect of the disclosure, the printed circuit board defines at least one cutout adjacent to the at least one lighting emitting device for channeling light from the at least one lighting emitting device through the printed circuit board.

According to yet another aspect of the disclosure, the top layer is a copper layer.

According to yet another aspect of the disclosure, the top layer includes a solder mask overlying the copper layer, the solder mask optionally having a color matching an applique to overlie the top layer.

According to yet another aspect of the disclosure, the at least one proximity sensor is a capacitive electrode.

According to another aspect of the disclosure, the subject system allows the at least one proximity sensor to be positioned close to a touch surface of the applique, while also reducing component count. Positioning the at least one proximity sensor close to the top surface provides improved detection sensitivity and an improved image of the at least one indicia through the applique. Furthermore, integrating the various components onto a single PCB reduces complexity of the design while reducing the risk of component failure and reducing costs associated with the system.

According to a further aspect of the disclosure, since the PCB is semi-transparent, it acts as an optical diffuser, and thus a stand-alone optical diffuser is not required. As such, air bubbles do not form between the PCB and a separate optical diffuser.

It is another aspect of the present disclosure to provide a keypad assembly for controlling a vehicle operation. The keypad assembly includes a printed circuit board including a top layer being formed of an electrically conductive material defining a front side of the printed circuit board and a base layer disposed under the top layer being at least partially formed of an optically transparent material defining the back side of the printed circuit board. An applique that is at least semi-transparent overlies the front side of the printed circuit board and defines a touch surface. The printed circuit board includes a plurality of indicia etched into the top layer and the plurality of indicia are defined by an absence of the electrically conductive material. The printed circuit board includes a plurality of light emitting device disposed on the back side of the printed circuit board. Each of the plurality of light emitting devices is associated with one of the plurality of indicia for selectively illuminating the optically transparent material of the base layer under the associated one of the plurality of indicia to illuminate the one of the plurality of indicia. The printed circuit board also includes a plurality of capacitive electrodes integrated into the front side of the printed circuit board. Each of the plurality of capacitive electrodes is aligned with and associated with one of the plurality of indicia for detecting a user object contacting the touch surface adjacent to the one of the plurality of indicia and outputting a corresponding detection signal.

According to yet another aspect of the disclosure, since the various electrical components are provided on the back side of the PCB, connections from the at least one proximity sensor to the components on the back side may simply extend through the PCB while avoiding the requirement for additional connectors.

According to yet another aspect of the disclosure, the electrically conductive material is copper.

According to yet another aspect of the disclosure, the keypad assembly further includes a driven shield positioned beneath the plurality of capacitive electrodes for minimizing the influence of parasitic capacitance.

According to yet another aspect of the disclosure, the keypad assembly further includes a driven shield positioned on the top layer to surround each of the plurality of capacitive electrodes for minimizing the influence of parasitic capacitance.

According to yet another aspect of the disclosure, the keypad assembly further includes a driven shield positioned on the top layer to surround at least two of the plurality of capacitive electrodes for minimizing the influence of parasitic capacitance.

According to yet another aspect of the disclosure, the driven shield is a portion of the top layer.

According to yet another aspect of the disclosure, the keypad assembly further includes at least one auxiliary sensor positioned on the front side of the printed circuit board.

According to yet another aspect of the disclosure, the at least one auxiliary sensor includes at least one water sensor for detecting a presence of water on the touch surface of the applique.

According to yet another aspect of the disclosure, the at least one auxiliary sensor is integrated into at least one of the plurality of capacitive electrodes.

According to yet another aspect of the disclosure, the keypad assembly further includes a ground layer extending over the back side of the printed circuit board for reducing electromagnetic interference.

According to yet another aspect of the disclosure, the plurality of light emitting devices are light emitting diodes.

According to yet another aspect of the disclosure, the light output of the plurality of light emitting devices are aligned generally parallel to the plane of the PCB.

According to yet another aspect of the disclosure, the optically transparent material of the base layer is a semi-transparent glass-reinforced epoxy laminate.

These and other aspects and areas of applicability will become apparent from the description provided herein. The description and specific examples in this summary are intended for purpose of illustration only and are not intended to limit the scope of the present disclosure.

### DRAWINGS

The drawings described herein are for illustrative purposes only of selected embodiments and not all implementations, and are not intended to limit the present disclosure to only that actually shown. With this in mind, various features and advantages of example embodiments of the present disclosure will become apparent from the following written description when considered in combination with the appended drawings, in which:

FIG. 1 is a perspective, exploded view of a first embodiment of a prior art keyless entry keypad assembly;

FIG. 2 is a perspective exploded view of a second embodiment of a prior art keyless entry keypad assembly;

FIG. 3 is a perspective side view of a motor vehicle equipped with a keyless entry system according to aspects of the disclosure;

FIG. 4 is a block diagram generally depicting the various components of the keyless entry system according to aspects of the disclosure;

FIG. 5 is a perspective, exploded view of an example embodiment of a keypad assembly for controlling a vehicle operation according to aspects of the disclosure;

FIG. 5A is a view of the keypad assembly of FIG. 4 connected to the rear of an applique, in accordance with an illustrative embodiment;

FIG. 6 is a perspective view of a back side of a printed circuit board of the subject assembly for controlling a vehicle operation according to aspects of the disclosure;

FIG. 7 is a perspective view of a front side of the printed circuit board of the subject assembly for controlling a vehicle operation according to aspects of the disclosure;

FIG. 8 is a cross-sectional view of a printed circuit board of the subject assembly for controlling a vehicle operation illustrating multiple layers of the printed circuit board according to aspects of the disclosure;

FIGS. 9A and 9B are cross-sectional views of a printed circuit board of the subject assembly for controlling a vehicle operation illustrating multiple layers of the printed circuit board and a hyperbolic shaped reflector according to aspects of the disclosure;

FIG. 10 is a cross-sectional view of a printed circuit board of the subject assembly for controlling a vehicle operation illustrating multiple layers of the printed circuit board and a symmetrically sloped reflector according to aspects of the disclosure;

FIG. 11 is a block diagram of a keypad of the subject assembly for controlling a vehicle operation illustrating the interconnection of the capacitive electrodes, protection components, Local Interconnect Network bus driver, light emitting diode driver, and light emitting devices to the microcontroller according to aspects of the disclosure; and

FIG. 12 is an electrical schematic of the controller unit of FIG. 4 for controlling the keyless entry system, and electrical connections with various components of the keyless entry system, in accordance with an illustrative embodiment;

FIG. 13 is an electrical schematic showing the electrical connections between the controller unit of FIG. 12 with the shield guards, the light emitting devices, and the proximity electrodes of the keyless entry system, in accordance with an illustrative embodiment; and

FIG. 14 is an electrical schematic showing the electrical connections between the controller unit of FIG. 12 with a light emitting device driver unit and the light emitting devices of FIG. 13, in accordance with an illustrative embodiment.

### DETAILED DESCRIPTION

In the following description, details are set forth to provide an understanding of the present disclosure. In some instances, certain circuits, structures and techniques have not been described or shown in detail in order not to obscure the disclosure. The term “controller unit”, or “controller” is used herein to refer to any machine for processing data or electrical signals, including data processing systems, computer systems, modules, electronic control units (“ECUs”), microprocessors or the like for providing control of the systems described herein, which may include hardware components and/or software components.

In general, the present disclosure relates to user interface systems of the type well-suited for use in virtually all motor vehicle applications. The user interface system of this disclosure will be described in conjunction with one or more example embodiments. However, the specific example embodiments disclosed are merely provided to describe the inventive concepts, features, advantages and objectives with sufficient clarity to permit those skilled in this art to understand and practice the disclosure.

More specifically, the present disclosure relates to a user interface system for controlling a vehicle operation, such as a keyless entry system. The user interface system includes a printed circuit board that has a front side and a back side. A top layer that is electrically conductive defines the front side of the circuit board. A plurality of indicia are etched into the top layer. An applique that is at least semi-transparent overlies the front side of the printed circuit board. At least one proximity sensor is integrated into the front side of the printed circuit board. Each of the at least one proximity sensors are associated with one of the plurality of indicia for detecting a user object adjacent to the associated indicia and outputting a corresponding detection signal. The printed circuit board further includes a base layer under the top layer. The base layer is at least partially formed of an optically transparent material and defines the back side of the printed circuit board. At least one light emitting device is positioned on the back side of the printed circuit board. Each of the at least one light emitting devices are associated with one of the plurality of indicia for selectively illuminating the optically transparent material under the associated one of the plurality of indicia to illuminate the associated indicia. A controller unit is coupled to the at least one proximity sensor and the at least one light emitting device and is configured to process the detection signal for controlling the vehicle operation and control selective illumination of the at least one light emitting device.

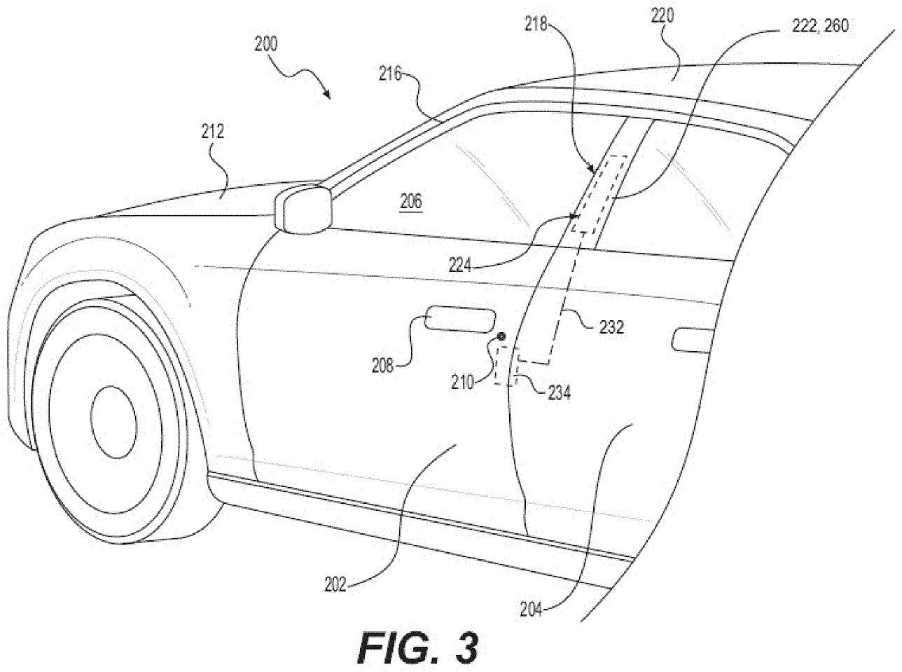

Referring initially to FIG. 3, a side view of a motor vehicle 200 is shown partially cut away to include a front driver-side door 202 and a rear driver-side door 204 which both provide access to a passenger compartment 206. Front door 202 is shown to include a door handle 208 and a key hole 210 provided for otherwise conventional locking and unlocking of a mechanically-activated latch mechanism 234 mounted within front door 202. Movement of door handle 208 functions to release front door 202 for movement relative to body portion 212 when the latch mechanism is unlocked. A similar door handle (not shown) could be provided on rear door 204 and interconnected to another latch mechanism (not shown) provided for locking and unlocking rear door 204. As will be detailed, each of the latch mechanisms may also include a power-operated actuator (not shown) for controlling the locking and unlocking functions in association with a keyless entry system 214, discussed in more detail below. Motor vehicle 200 is shown to also include an A-pillar 216, a B-pillar 218 and a roof portion 220.

In the example shown in FIG. 3, B-pillar 218 is covered by a cover plate assembly 222, such as an applique 260 as described in more detail hereinbelow. A keypad assembly 224 associated with the keyless entry system 214 of the present disclosure is mounted to B-pillar 218 within cover plate assembly 222 at the location identified by the dashed lines. Keypad assembly 224 is mounted between a structural portion of B-pillar 218 and cover plate assembly 222. As an alternative, keypad assembly 224 could be mounted to front door 202 in proximity to handle 208. Other mounting positions of the keypad assembly 224 are possible, such as on a liftgate, or decklid.

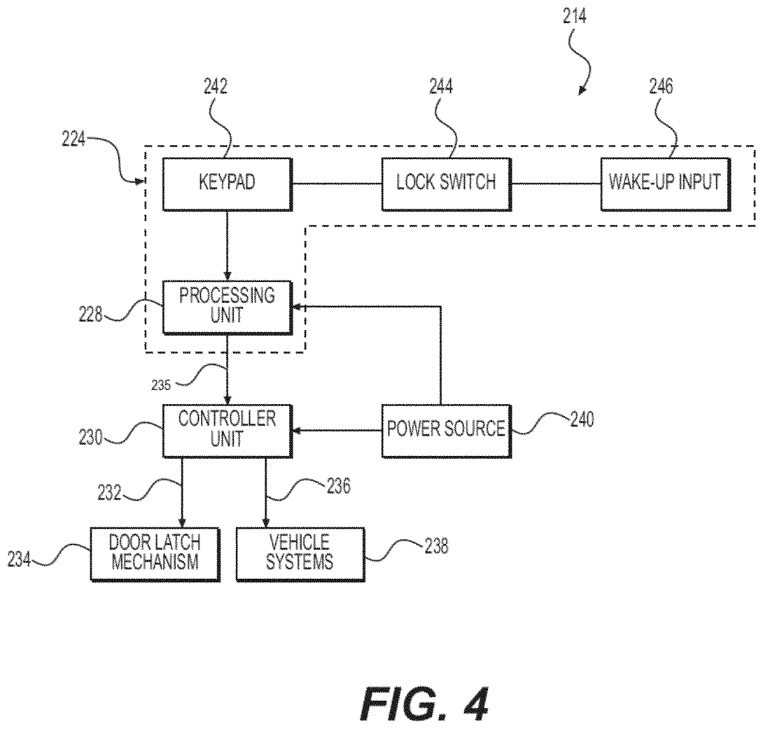

Referring now to FIG. 4, a block diagram of various components of the keyless entry system 214 is provided. As seen, keypad assembly 224 includes or is connected to a processing unit 228, also referred to as a controller unit 228, such as a microprocessor, which, in turn, communicates with a vehicle controller unit 230. Vehicle system controller unit 230 provides an electrical output along line 232 to a power-operated actuator of a door latch mechanism 234. As is known, vehicle system controller unit 230 may also provide electrical outputs along lines 236 for controlling other vehicular systems 238 (e.g., power release of a trunk or liftgate, actuation of the lights and/or security functions, and activation of the ignition system and/or the vehicle's heating system, etc.). A power source, such as a battery 240, (e.g., a vehicle main battery, or a backup energy source, such as a supercapacitor, or other battery) may provide power to processing unit 228 and the vehicle system controller unit 230. As will be detailed, keypad assembly 224 includes a capacitive touch keypad unit 242, a capacitive touch lock switch 244 and a force-dependent mode input device 246. It is understood that the keypad assembly 224 may alternatively also include any combination of thereof, for example it may include a capacitive touch keypad unit 242 and a capacitive touch lock switch 244.

The operation of the keyless entry system 214 of FIG. 4 is configured to permit selective access to passenger compartment 206 via front door 202 or, in the alternative, both doors 202, 204 when the operator (hereinafter, the “user”) enters an authorization code via keypad unit 242. The authentication code entered is transmitted to processing unit 228 where it is compared to a correct or verification code stored in memory. If the entered passcode matches the verification code, a signal is sent to vehicle system controller unit 230 which, in turn, will unlock latch mechanism 234 and permit operation of door handle 208 to release front door 202 (or both doors 202, 204) and allow access to passenger compartment 206. Those skilled in the art will recognize that this rudimentary control diagram is merely an example of only one suitable arrangement for the keyless entry system 214. For example, vehicle controller unit 230 may undertake the above described comparison issue an authorization command to the controller unit 228.

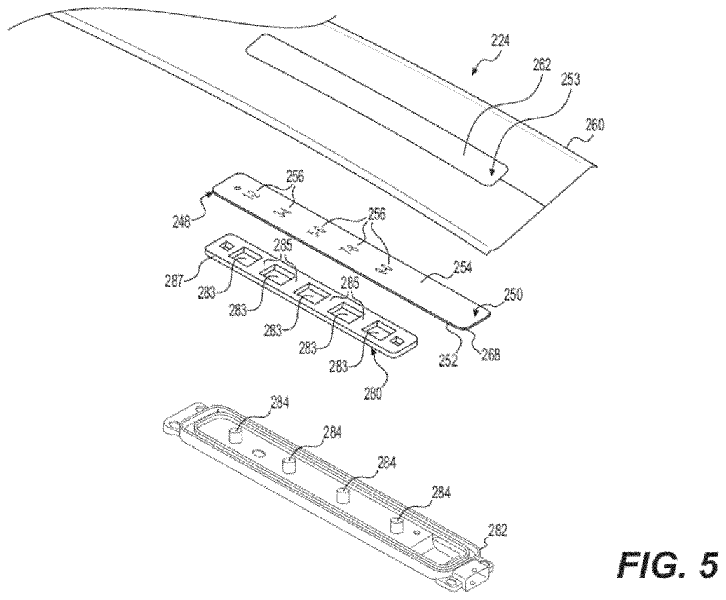

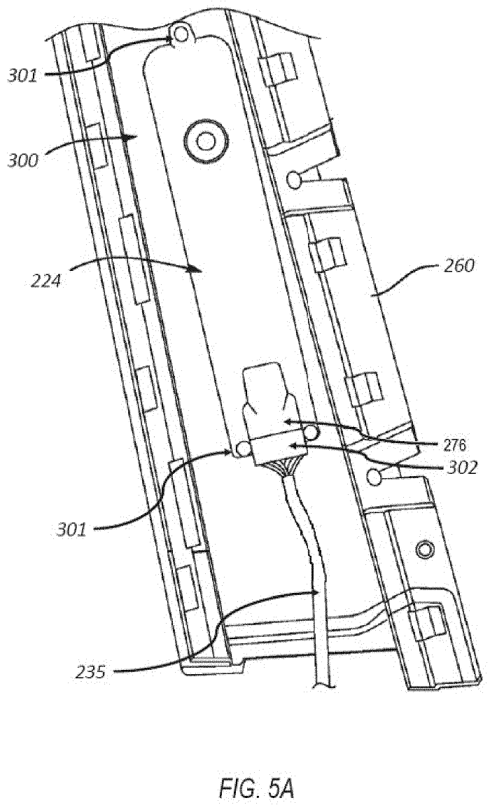

Referring now to FIG. 5, an embodiment of the keypad assembly 224 for controlling a vehicle operation according to an aspect of the disclosure is provided. More particularly, the embodiment of the keypad assembly 224 shown in FIG. 5 can be used as part of the keyless entry system 214. It should be appreciated that the subject keypad assembly 224 could be utilized to perform other vehicle operations.

Referring now to FIG. 5A, in addition to FIGS. 4 and 5, an embodiment of the keypad assembly 224 for controlling a vehicle operation is shown connected, via fasteners 301 to the rear side 300 of the applique 260. The applique 260 comprises a structure at least partially circumscribing a receptacle 253 illustratively formed on the rear side 300 of the applique 260 for receiving at least a portion of the keypad assembly 224 therein. Alternatively, the keypad assembly 224 may be positioned directly juxtaposed to the rear side 300. A wire harness 302 connected to the surface mount connector 276 connected to the PCB 248 is provided to facilitate electrical connection of the circuitry of the keypad assembly 224 with the wires 235 and external systems, such as the latch 234.

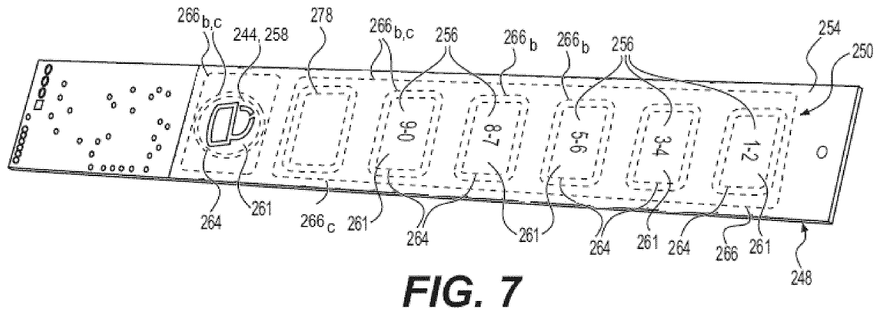

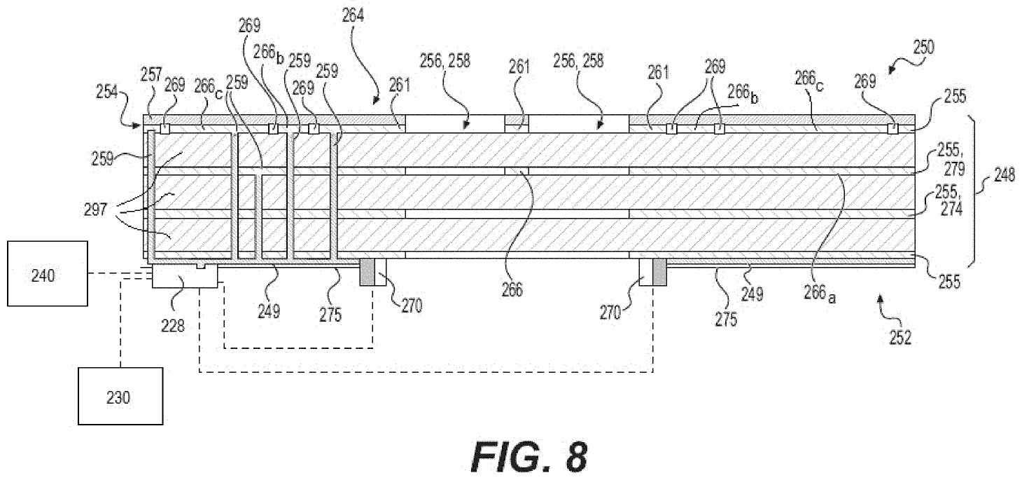

Now referring to FIG. 5 and FIG. 8, the keypad assembly 224 includes a printed circuit board (PCB) 248 having a front side 250 and a back side 252. A top layer 254 that is electrically conductive defines the front side 250 of the PCB 248. It should be appreciated that the top layer 254 could be a copper layer 255 or formed of another electrically conductive material. Illustratively, the top layer 254 includes a solder mask 257, which may be provided in a color to match the applique 260 so as to visually blend the PCB 248 with the overlying applique 260 when the PCB 248 and the overlying applique 260 are juxtaposed. For example, PCB 248 may be fully or partially received within a dimensionally mating receptacle 253 formed within the rear side 300 of the overlying applique 260, the receptacle 253 having a transparent or semi-transparent covering portion defining a touch surface 262 adjacent the receptacle 253, and illustratively opposite sides of the applique 260, so as to seal the PCB 248 from the exterior environment while allowing light to pass there though. A plurality of indicia 256, 258 are etched into the top layer 254. In the illustrative example, material in the top layer 254 is removed to shape the indicia, by etching as an example, so as to allow light to pass through the area defined by the removed material. Other manners of forming the indicia are also possible, such as only etching the top layer 254 to remove the border outline of the indicia so that light only passes through the outline. In the example embodiment, the indicia 256, 258 include a plurality of numerals 256 and a lock indicia 258 identifying the lock switch 244 (FIG. 7). It should be appreciated that other numerals, letters or symbols could be utilized including, but not limited to, a separate unlock button. The term indicia is used herein to refer to any type of number, letter, symbol, marking, logo, graphic, images, indications, distinguishing mark, or the like.

An applique 260 overlies the front side 250 of the PCB 248. The applique 260 protects the PCB 248 while also providing a touch surface 262. It should be appreciated that during use, the indicia 256, 258 are configured to be visible through the applique 260. Thus, the applique 260 can be semi-transparent or completely transparent. Or, only the portion of the applique 260 defining the touch surface 262 can be semi-transparent or transparent. The thickness of the applique 260 may vary, and for example the thickness may be thinner in the area of the touch surface 260 so as to define the semi-transparency of the touch surface 262.

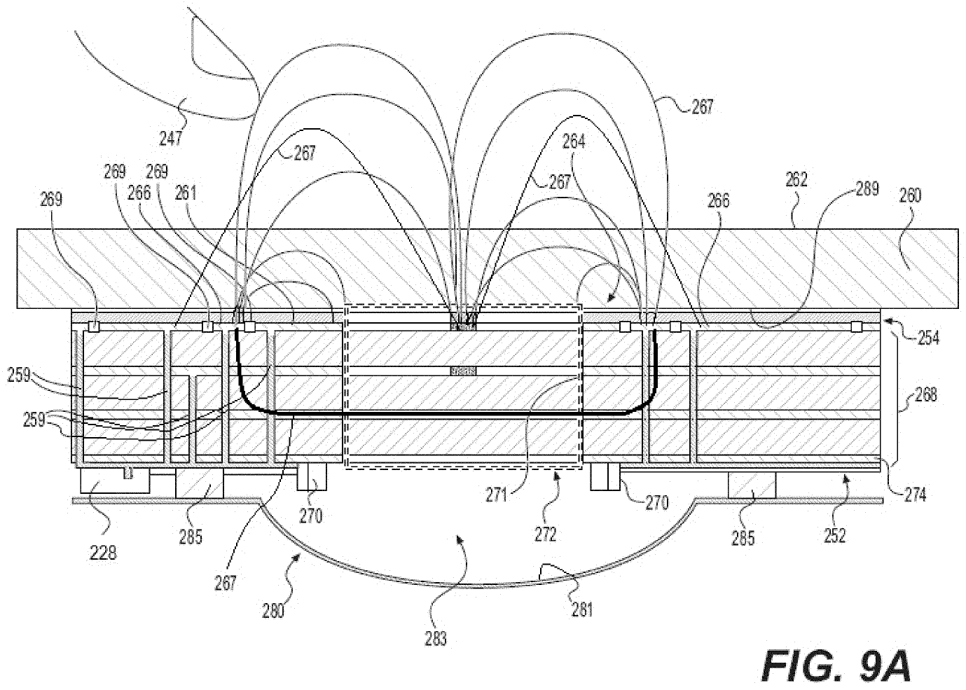

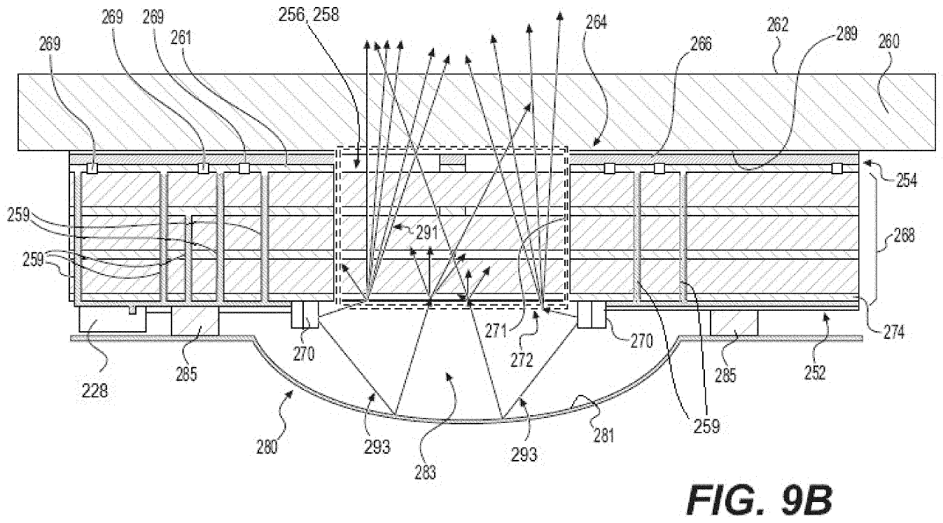

A plurality of proximity sensors 264 (schematically shown in FIG. 7) are integrated into the front side 250 of the PCB 248 beneath the applique 260 and electrically coupled to the controller unit 228, for example via electrical connections 259, such as vertical interconnect accesses (e.g., a via), extending through the PCB 248 to the opposite the back side 252 connecting with electrical traces 249 formed in the PCB 248 back side 252, with the various copper layer(s) 255. Traces 249 may be formed by etching into the back side conductive layer 274 and/or deposited onto the back side conductive layer 274, as examples, for providing electrical connections between the various components. Each of the proximity sensors 264 comprises a capacitive electrode 261 and is associated with one of the indicia 256, 258. It should be appreciated that any number of proximity sensors 264 could be used, and while the proximity sensors 264 are illustrated as capacitive electrodes, the proximity sensors 264 could include various other types of proximity sensors 264, such as, but not limited to radar sensors, or a capacitive force based sensor. The proximity sensors 264 are each configured to detect movement of a user object adjacent to the touch surface 262 of the applique 260 adjacent to the proximity sensor 264, or a touching of the touch surface 262 of the applique 260 adjacent to the proximity sensor 264. For example, the proximity sensor 264 may be a surface capacitive touch sensor type configured to detect a change in capacitance of the sensor 264 caused by approach of an object, such as a finger 247 (FIG. 9A) to the sensor 264. As an example, of a surface capacitive touch sensor configuration, a disruption in a uniform electrostatic field 267 (FIG. 9A) generated by an applied voltage from the controller unit 228 to the capacitive electrode 261 of the proximity sensor 264 formed in the conductive top layer 254 as delimited by an insulator 269 or removed (e.g., etched) top layer 254 areas, is sensed by the controller unit 228 representing the proximity of a user's finger. Other capacitive sensing techniques are contemplated, such as configurations whereby an oscillation signal, for example as supplied by the controller unit 228 is applied to the capacitive electrode 261 at a consistent voltage across the capacitive electrode 261. The generated field 267 is disrupted by a conductive material or object, such as a finger 247, entering the field 267. The controller unit 228 is able to correlate the differences in supplied and detected oscillations in order to detect and determine the proximity of the finger 247 or contact with the touch surface 262.

As illustrated in FIGS. 9A and 9B, with the provision of the capacitive electrode 261 on the front side 250 of the PCB 248, the field 267 can be provided close to the touch surface 262 and extend further away from the touch surface 262. The proximity sensors 264 are also configured to output a corresponding detection signal based on the detected input. For example, if a user touches or moves his or her hand adjacent to the applique 260 near the “1-2” indicia, the proximity sensor 264 beneath the “1-2” indicia will detect the movement and output a corresponding detection signal to the controller unit 228. It should be appreciated that in embodiments in which the proximity sensors 264 detected movement of a user object adjacent to the applique 260, the proximity sensors 264 may detect movement even if external objects like dirt or ice are positioned over the applique 260 on the touch surface 262.

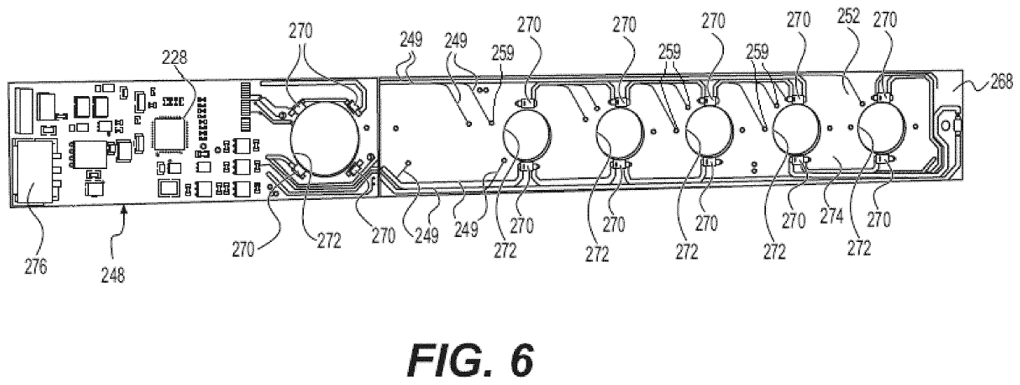

According to an aspect of the disclosure, a driven shield 266 (e.g. 266a) that is separate from the top layer 254 is disposed under at least a portion of the top layer 254 for the proximity sensors 264 to minimize influence of parasitic capacitance that comes from sheet metal ground associated with the vehicle 200 and avoid false activations or detections, either from a misplaced user input (e.g., a finger 247 overlapping the detection zones of two adjacent proximity sensors 264), or from rain or water dripping across the multiple detection zones of the proximity sensors 264. The driven shield 266 is illustratively in electrical connection with the controller unit 228 to receive a driven voltage through the electrically conductive path of the vias 259, and assists to direct the field 267 away up and away from the capacitive electrode 261 as well as reducing parasitic capacitance, as an example, to improve proximity detection. Further, a portion of electrically conductive top layer 254 may be configured to act as the driven shield 266 (e.g. 266b, 266c) surrounding at least two of the capacitive electrodes 261, and in FIG. 6, shown as surrounding six capacitive electrodes 261, also being illustratively in electrical connection with the controller unit 228 through the vias 259. Specifically, a portion of the top layer 254 may have insulators 269 formed thereon, for example as removed (e.g., etched) top layer 254 areas adjacent the capacitive electrode 261 forming the proximity sensors 264 to define the driven shield 266.

The PCB 248 further includes a base layer 268 under the top layer 254. The base layer 268 defines the back side 252 of the PCB 248. The base layer 268 is at least partially formed of an optically transparent material. According to an aspect the base layer 268 can be a semi-transparent glass-reinforced epoxy laminate (e.g., FR4).

At least one light emitting device 270 is disposed under the at least one indicia 256, 258. In the example embodiment, the least one light emitting device 270 includes a plurality of light emitting devices 270 positioned on the back side 252 of the PCB 248 for illuminating the indicia 256, 258 and are aligned with and associated with each of the indicia 256, 258 for selectively illuminating the optically transparent material of the base layer 268 under the associated one of the plurality of indicia 256, 258 to illuminate the associated indicia 256, 258. The light emitting devices 270 may be attached to the PCB 248 and underlie the indicia 256, 258; nevertheless, the light emitting devices 270 may also be separate from the PCB 248, for example.

In the example embodiment, two light emitting devices 270 are provided and mounted to the back side 252 opposite and displaced from one another about the indicia 256. In the example embodiment, four light emitting devices 270 are provided and mounted to the back side 252 opposite and displaced from one another about the indicia 258. The light output of each of the plurality of light emitting devices 270 are aligned generally parallel to the plane of the PCB 248. For example the light outputted from the light emitting device 270 may scattered at +/−forty five degrees relative to the plane surface of the PCB 248, but other light angles are possible (see FIG. 9B for example). This alignment of the light emitting device 270 can insure that light from the light emitting device 270 may directly enter the material of the PCB 248, or be reflected by the reflector 281, and allows the reflector 281 size to be reduced as compared with light outputted perpendicular to the plane surface of the PCB 248, but such a configuration is also contemplated by the present disclosure. Other positioning and number of the light emitting devices 270 are possible, such as providing three light emitting devices 270 radially distributed about the indicia 256 along a circular pattern on the back side 252.

In the example embodiment, the light emitting devices 270 are light emitting diodes (LEDs); however, other light emitting devices 270 could be utilized. It should be appreciated that since the base layer 268 of the PCB 248 is of a semi-transparent material 297, it serves as an optical diffusor, allowing some light in a diffused pattern 291 (FIG. 9B) to pass therethrough from the light 293 emitted by the emitting devices 270 to the indicia 256, 258. In an embodiment as shown in FIGS. 9A and 9B, the PCB 248 may be formed from as multilayer PCB having at least one layer of conductive material layer 255 which is buried in the center of the material of the base layer 268 with selective portions of the at least one layer of conductive material layer 255 being removed during manufacturing of the base layer 268 so as to allow light to pass through the base layer 268. Other configurations of the PCB 248, are possible, such as a PCB having only a conductive top layer 254 (e.g. a copper layer 255), and back side conductive layer 274, with one layer of semi-transparent material 249 disposed therebetween.

The controller unit 228 is electrically coupled to the proximity sensors 264 and the light emitting devices 270 and is configured to process the detection signals from the proximity sensors 264 for controlling the vehicle operation, and to control selective illumination of the light emitting devices 270. It should be appreciated that the controller unit 228 could take various forms and we located at other various places on the vehicle 200 (e.g., attached to the PCB 248). The controller unit 228 includes electronics suitable for providing the necessary voltage to the plurality of electrodes 261 and other driven layers 266, so the capacitances and changes/disturbances to the electrostatic field 267 may be detected. Such changes in capacitance occur when a user places a finger 247 on the touch surface 262 on or near the location of one of the electrodes 261. When the capacitance changes, the electronics on the controller unit 228 identify the capacitance change as a selection of a particular electrode 261 which is identified to the user by the indicia 256. When the selections of a sequence of electrode 261 are made in the correct predetermined combination as may be stored in memory in the controller unit 228, the controller unit 228 may send a signal through the connectors and the wires 235 to the latch 234 (directly or indirectly via the controller unit 230) to have the side door 202 unlatched by the door latch (not shown), as an example of control of a vehicle operation. The door handle 208 can then be used to open the door 202. The sequence of selection may also further include the selection of the electrode 261 associated with indicia 258, or the selection of electrode 261 associated with the indicia 258 may be performed alone to control the vehicle operation, such as locking the latch 234.

As best illustrated in FIG. 6 and FIGS. 9A and 9B, the PCB 248 includes a plurality of cutouts 272 in the back side 252, each placed adjacent to one or more of the light emitting devices 270 for forming part of a light channel 271 for channeling light through the PCB 248. The cutouts 272 may define a complete opening or may be comprised of a sheet of material that is thinner than the rest of the PCB 248 and/or more transparent than the rest of the PCB 248 (e.g., the cutouts 272 may extend into a portion of the PCB 248 material). In another embodiment, and as illustrated in FIGS. 8 to 10, the cutout 272 is only formed in the back side conductive layer 274, which is illustratively made from copper, for example by removing material such as through etching the conductive layer 274. The back side conductive layer 274 also optionally having a solder mask 275 overlying the copper backside layer 274, which is also removed during the etching process so as to allow light emitted by the light emitting devices 270 to enter the light channel 271 (e.g. penetrate the layers of layer of semi-transparent material 249).

In the multilayer PCB embodiment of FIGS. 8, 9A, 9B, and 10, the light channel 271 may be formed by eliminating the copper material forming the at least one layer of conductive material 255 which are buried in the center of the material of the base layer 268 during the manufacture of the PCB 248, whereby copper material is strategically not deposited about the channel 271 area, so as to form a light channel 271 extending through the PCB 248 to allow light to pass from the back side 252 to the front side 250.

In the illustrative embodiment of FIGS. 6, 9A, and 9B, the light channel 271 is illustratively formed as having a cylinder shape extending from the back side 252 to the front side 250, with each conductive layer 255 of the base layer 268 having similarly circularly shaped area of removed material (e.g., formed by the absence of the non-light penetrating copper conductive material). Optionally, the layer 279 beneath the top layer 254 may have a mirrored pattern of removed material similar to that of the top layer 254, for example so as to match the formed indicia 256, 258 on the top layer 254 so as to increase the area of the driven shield 266a and improve the driven shield effect.

According to an aspect of the disclosure, the PCB 248 may further include a ground layer 274 extending along at least a portion of the back side 252 (e.g., a metal layer within the PCB 248) to aid with reducing electromagnetic interference. The ground layer 274 may alternatively define the back side 252. If the PCB 248 includes the ground layer 274, it may also be etched at a regions opposite the indicia 256, 258 on the front side 250 to further form the light channel 271. For example a circular region can be etched to form the cutout 272 to provide for light transmittal there through in the configuration where the ground layer 274 is provided on the back side 252.

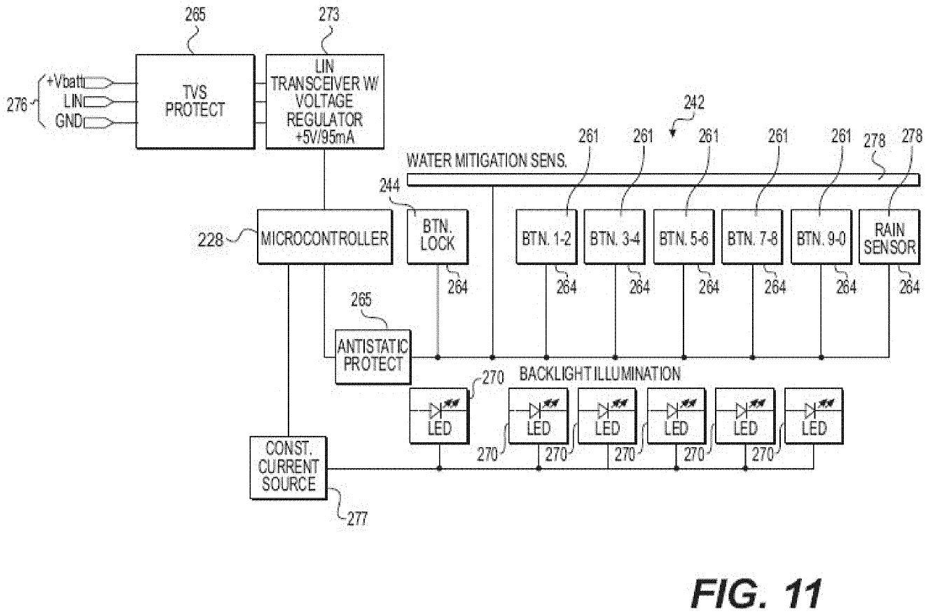

Additional electrical components are positioned on the back side 252 of the PCB 248 including, but not limited to, the controller unit/microcontroller 228, capacitors, resistors, protection components 265 (FIG. 11), a Local Interconnect Network (LIN) bus driver 273 (FIG. 11), a surface mount connector 276 for external wiring, and an LED driver 277 (FIG. 11) for the light emitting devices 270.

Additional auxiliary sensors can be positioned on the front side 250 of the PCB 248 and electrically connected to the controller unit 228. For example, a water sensor 278 may be provided for sensing water. As illustrated in FIG. 7, the water sensor 278 may be positioned between the “9-0” indicia and the lock indicia 258 of the lock switch 244. The water sensor 278 may be utilized to minimize the effects of fluid caused by events like rain or a car wash on the assembly 224. Furthermore, the water sensor 278 may be configured with the controller unit 228 to enable an automatic signal to close the windows of the vehicle 200 if water is detected. The auxiliary sensors 278 could also be integrated into one or more of the proximity sensors 264. For example, one of the capacitive electrodes could be utilized as a water sensor 278.

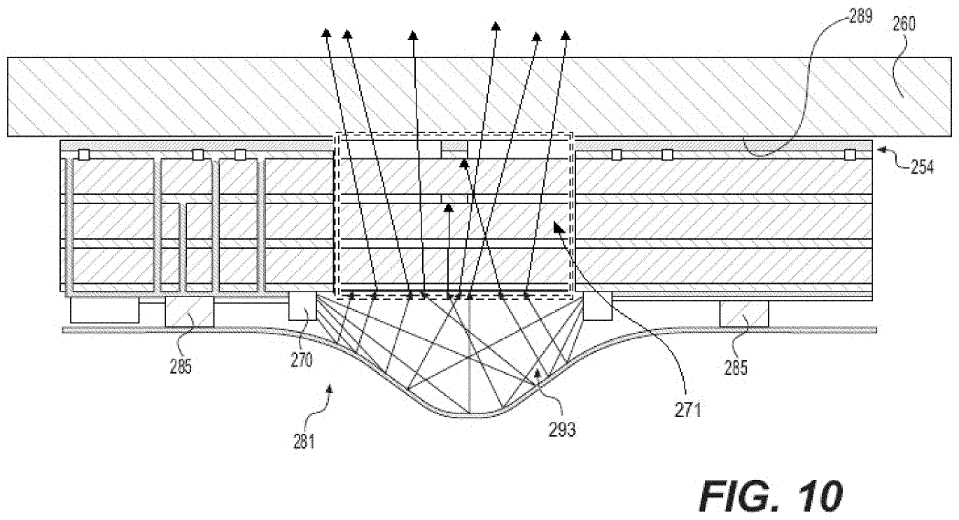

A reflector assembly 280, including at least one reflector surface 281 each associated with and placed adjacent to the one or more of the light emitting devices 270, is disposed against the back side 252 of the PCB 248 for reflecting light from the light emitting devices 270 through the at least partially optically transparent material of the base layer 268 of the PCB 248 and through the indicia 256, 258. The reflector 280 is configured to reflect light emitted by light emitting device 270 away from the PCB 248 back towards and through the PCB 248 and prevents light leakage around the frame 287 (e.g., periphery) of the PCB 248, and leakage between the PCB 248 and sub-frames 285 separating adjacent reflector surfaces 281, the frame 287 and the sub-frames 285 forming a sealed light cavity 283 to seal light from a light emitting device 270 associated with one indicia 256, from bleeding into an adjacent light channel 271 of an adjacent indicia 256. In an illustratively embodiment of FIG. 10, the reflector 281 is a symmetrically sloped reflector for reflecting light from an adjacent light emitting device 270 towards the PCB 248. In another illustrative embodiment of FIGS. 9A and 9B, the reflector 281 is hyperbolic shaped. Furthermore, a back cover 282 supports the reflector 280 and PCB 248, for example back cover 282 illustratively provides the structure to connect and position the PCB 248 and reflector 280 to the rear side 300 of the applique 260. The back cover 282 may include a plurality of mounts 284 for holding the PCB 248 and/or reflector 280. The mounts 284 may be illustratively formed of a resilient rubber material and assist in ensuring that the PCB 248 is properly aligned flush with the inner surface 289 of the receptacle of the applique 260 so as to avoid the formation of air pockets between the surface 289 of the applique 260 and the top layer 254 which may affect and influence the capacitance and thus detection of the electrodes 261. The mounts 284 act to urge the top layer 254 towards the inner surface 289 of the applique 260.

It should be appreciated that integrating the various electronic components (e.g., controller unit 228, proximity sensors 264) into the PCB 248 of the keypad assembly 224 of the subject system 214, as described, advantageously allows the proximity sensors 264 to be positioned close to the touch surface 262 on the applique 260, while also reducing component count. Positioning the proximity sensors 264 close to the touch surface 262 of the applique 260 provides improved sensitivity of the proximity sensors 264 and increased visibility of the indicia 256, 258. It should be appreciated that part of the reason the proximity sensors 264 may be positioned closer to the applique 260 is because there is no separate optical mask between the proximity sensors 264 and the PCB 248.

It should also be appreciated that integrating the various components (e.g., optical mask and diffusor) into the PCB 248 also provides reduced complexity of the system 214, reduced risk of failure of components of the system 214, and reduced costs associated with the system 214.

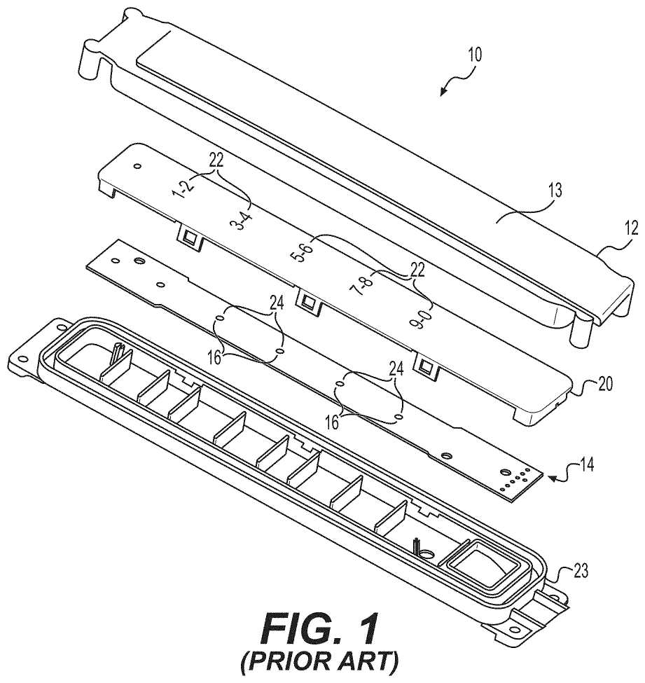

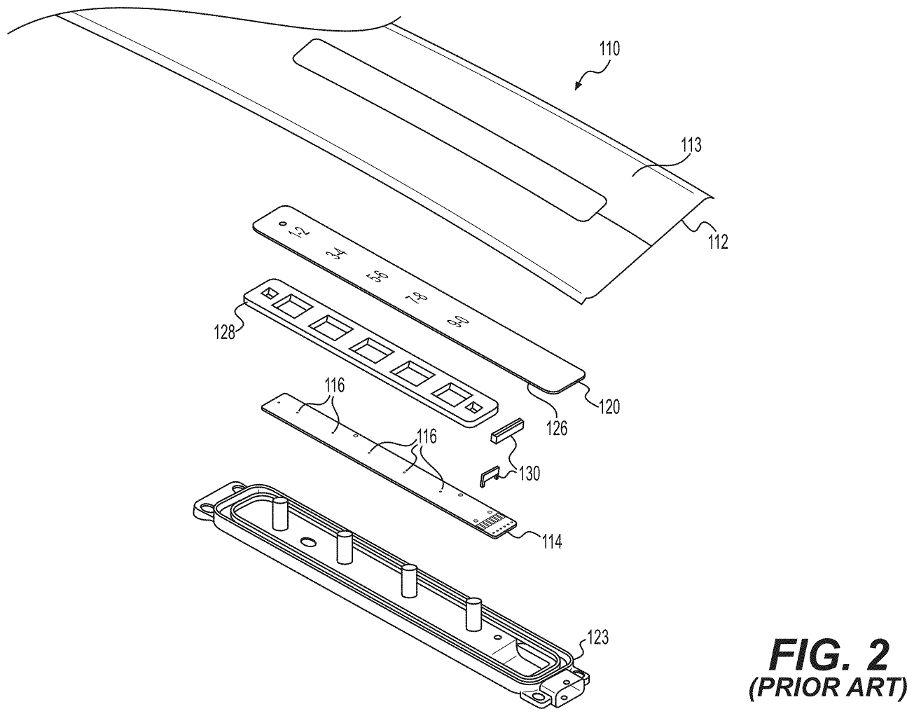

It should also be appreciated that the PCB 248 advantageously serves as a light diffusor, light mask, and proximity sensor while at the same time supporting the various components and positioning the proximity sensors 264 close to the top surface of the applique 260. Since the PCB 248 acts as an optical diffuser, a separate optical diffuser is not required as in the keypad assemblies 10, 110 of FIGS. 1 and 2. As such, separation of the mask from the PCB 248, and thus the formation of air bubbles, does not occur.

It should also be appreciated that since the components (e.g., light emitting devices 270 and controller unit 228) are provided on the back side 252 of the PCB 248, additional connectors are not needed and connections from the proximity sensors 264 to the components on the back side 252 may extend through the PCB 248, for example via the electrical connections 259.

It should also be appreciated that since the proximity sensors 264 are provided on the PCB 248, and thus very close to a PCB ground plane of the PCB 248 (e.g., ground layer 274), electromagnetic interference is reduced.

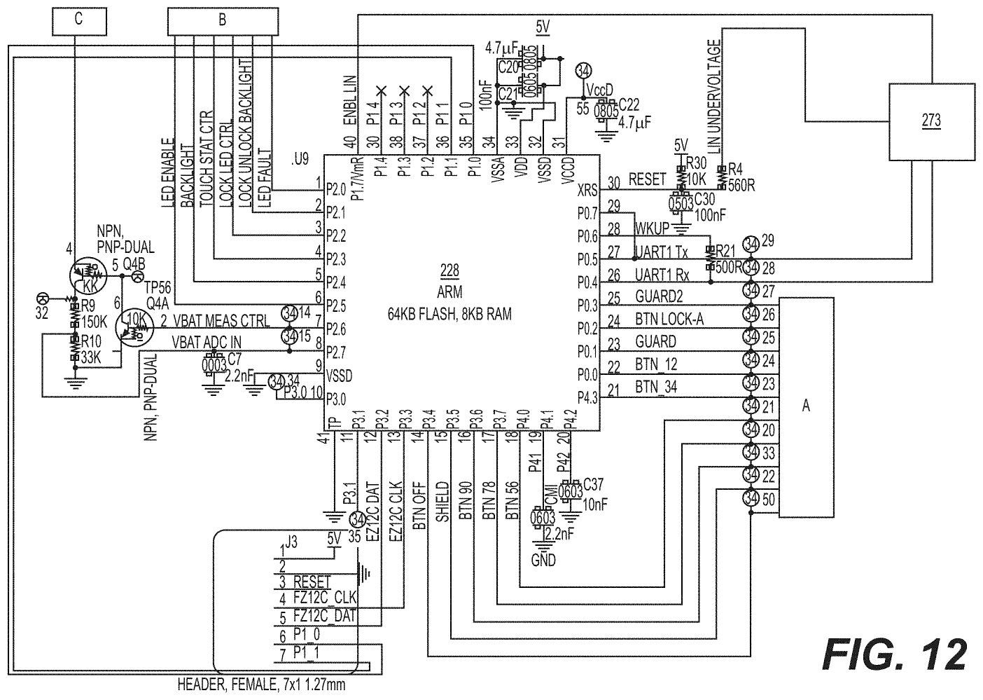

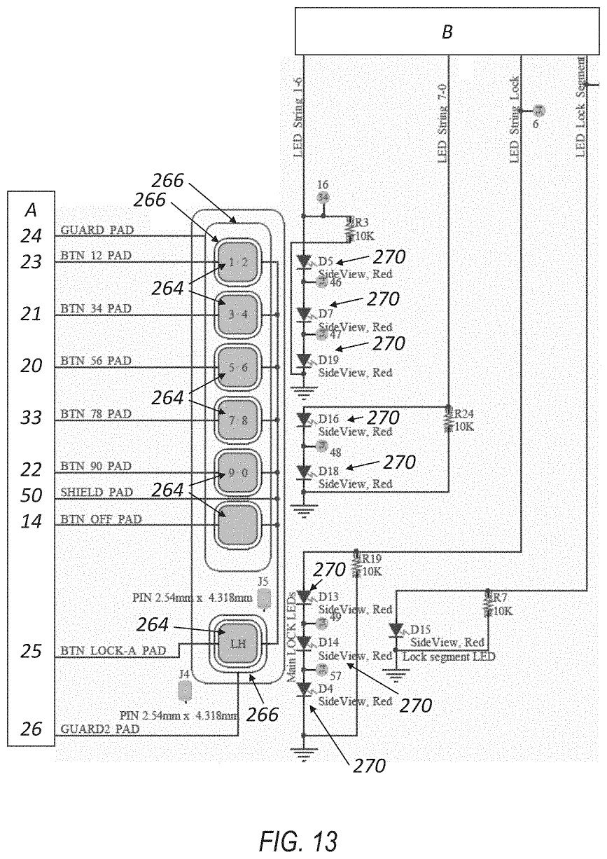

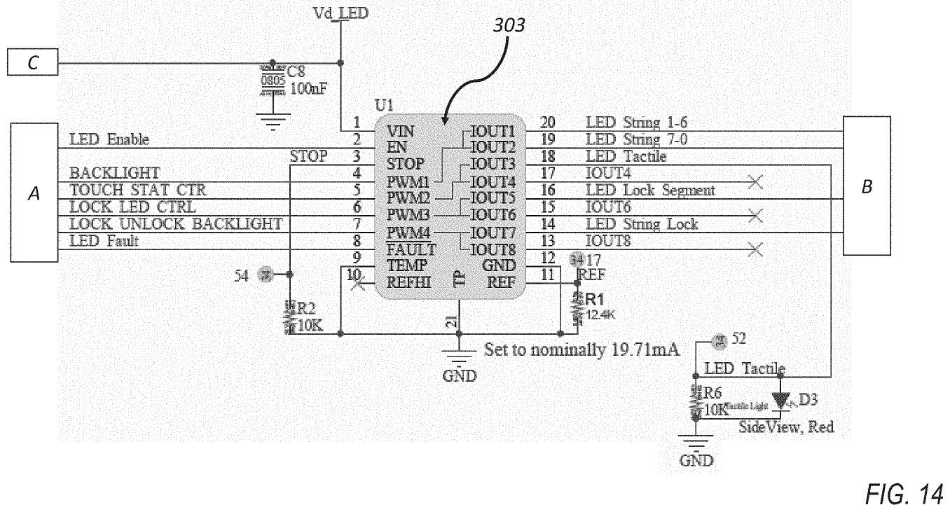

Now referring to FIGS. 11 to 14, there are shown the electrical circuit diagrams interconnecting the various electrical components of the keypad assembly 224. Illustratively, the controller unit 228 is a microprocessor having a number of input and output ports for receiving and sending electrical signals. In particular, controller unit 228 is connected to the electrodes 261 through a number of electrical signal lines (e.g. signal lines 23, 21, 20, 33, 22, 14, 25), shown as interconnected through connecting block A, shown only for purposes of illustrating an electrical connection between electrical signal lines provided in different figures. Also, controller unit 228 is connected to the driven shield 266 through a number of electrical signal lines (e.g. signal lines 24, 26, 50), also shown as interconnected through connecting block A. Controller unit 228 is also illustrated as being in electrical connection with a light emitting device driver 303 via connector block D, the light emitting device driver 303 being in electrical communication with the LEDs 270 via connector block B for providing current and/or voltage to operate the LEDs 270. The light emitting device driver 303 may illustratively be the constant current circuitry (e.g. constant current source 277) for driving the LEDs to about, and as an illustrative example, 11,000 nits minimum average brightness at nominal supply voltage (such as between about 9 and 16 volts DC, such as about 13.5 Volts DC), with a generally uniform illumination. The LEDs 270 may be configured to emit colored light or white light, depending on the particular application, and may operate at a maximum current of about 100 mA and may be operable at temperatures between about −30 degrees C. and +65 degrees C. Also, controller unit 228 is connected to the power source 240 via connecting block C.

Those skilled in the art will also recognize that the present disclosure has applicability to various user interface systems, including keyless entry system, both passive and non-passive, for controlling actuation of additional vehicular functions. A non-limiting listing of such additional functions may include release of the gas tank cover plate, power window control, power release of vehicular doors in addition to lock/unlock functionality, and lock/unlock and power release of liftgates. It should also be recognized that the force-dependent mode input device 246 may be located remotely from the capacitive-based user-input interfaces (e.g., proximity sensors 264 of the keypad assembly 224). The force-dependent mode input device 246 is not intended to merely wake-up or actuate the proximity sensors 264 of the keypad assembly 224, but can also be part of a multi-stage control protocol for controlling a vehicle component. The present system 214 also contemplates use of second user-input interfaces for gesture recognition control systems.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Those skilled in the art will recognize that the inventive concept disclosed in association with the example keyless entry system 214 can likewise be implemented into many other vehicular systems to control one or more operations and/or functions.

Example embodiments are provided so that this disclosure will be thorough, and will fully convey the scope to those who are skilled in the art. Numerous specific details are set forth such as examples of specific components and devices to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device or assembly may be otherwise oriented (rotated 90 degrees or at other orientations) and the spatially relative descriptions used herein interpreted accordingly.

What is claimed is:

1. A keypad assembly for controlling a vehicle operation, comprising:
an applique having a outer side defining an exterior surface and an opposite inner side, the applique having at least a semi-transparency; and
a printed circuit board having an at least partially optically transparent base layer provided between a front side and a opposite inner side of the printed circuit board, the front side positioned adjacent the opposite inner side of the applique, the printed circuit board comprising:
at least one proximity sensor integrated into the front side of the printed circuit board for detecting a proximity of a user to the exterior surface;
at least one indicia integrated into the front side of the printed circuit board for indicating the location of the at least one proximity sensor to the user; and
at least one light emitting device connected to the opposite inner side of the printed circuit board for selectively illuminating the base layer under the at least one indicia to illuminate the at least one indicia;
wherein the opposite inner side of the printed circuit board comprises at least one opening to allow light emitted by the at least one light emitting device to penetrate the optically transparent base layer to illuminate the at least one indicia.

2. The keypad assembly of claim 1, wherein the front side of the printed circuit board comprises a top layer of material, wherein the indicia is formed by an absence of the top layer material, and wherein the back side of the printed circuit board comprises a back layer of material, wherein the at least one opening is formed by an absence of the of the bottom layer material.

3. The keypad assembly of claim 2, wherein the layer beneath one of the indicia is formed having a mirrored absence material similar to that of the top layer material to match the formed indicia.

4. The keypad assembly of claim 2, wherein the top layer of material and the bottom layer of material are each formed from a layer of electrically conductive material and the at least one opening is formed by etching of the electrically conductive material.

5. The keypad assembly of claim 4, wherein the at least one opening and the at least one indicia are formed by etching of opposite regions of the front side and back side.

6. The keypad assembly of claim 4, wherein at least one light emitting device is mounted to the bottom layer of electrically conductive material and distributed about the at least one opening.

7. The keypad assembly of claim 2, wherein the printed circuit board is a multilayer printed circuit board having a light channel formed by an absence of material from each layer of the multilayer material.

8. The keypad assembly of claim 1, wherein the opening is circular.

9. The keypad assembly of claim 1, wherein the printed circuit board comprises a shaped light channel extending from the back side to the front side of the printed circuit board for channeling light from the at least one lighting emitting device through a center of the optically transparent base layer.

10. The keypad assembly of claim 9, wherein the light channeled by the light channel does not penetrate outside the light channel.

11. The keypad assembly of claim 9, wherein the light channel comprises a cylindrical shape.

12. The keypad assembly of claim 1, further comprising a reflector assembly having at least one sub-frame each forming a sealed light cavity sealing light emitted by the at least one light emitting device for an associated one of the at least one indicia.

13. The keypad assembly of claim 1, wherein the printed circuit board front side is directly positioned next to the opposite inner side of the applique.

14. The keypad assembly of claim 1, wherein vertical interconnect accesses extend through the printed circuit board to electrically connect the at least one proximity sensor with a controller mounted on the backside of the printed circuit board.

15. The keypad assembly of claim 14, wherein a plurality of traces are provided on the backside for connecting the at least one light emitting device to the controller.

16. The keypad assembly of claim 1 assembly, wherein one of the least one indicia is a lock symbol.

17. The keypad assembly of claim 1 assembly, wherein the front side of the printed circuit board comprises a color that matches with the color of the applique.

18. The keypad assembly of claim 1 assembly, wherein the applique comprises a receptacle for receiving at least a portion of the keypad assembly.

19. The keypad of assembly claim 1, wherein at least one proximity sensor is configured to encircle the at least one indicia.

20. A keypad assembly for controlling a vehicle operation, comprising:
an applique having a first side defining a surface and an opposite side, the applique having at least a semi-transparency; and
a printed circuit board having an optically transparent base layer provided between a front side and a back side of the printed circuit board, the front side positioned adjacent the opposite side of the applique, the printed circuit board comprising:
at least two proximity sensors integrated into the front side of the printed circuit board for detecting a proximity a user to the surface;
at least two indicia integrated into the front side of the printed circuit board each for indicating the location of an associated one of the at least two proximity sensors;
at least two light emitting devices mounted to the back side of the printed circuit board and each associated with one of the at least two indicia for selectively illuminating the base layer under an associated one of the at least two indicia;
at least two shaped light channels each associated with one of the at least two indicia and each extending from the back side to the front side;
at least two openings provided on the back side of the printed circuit board each configured to allow light to enter one of the light channels associated with one of the at least two indicia there through; and
at least two light emitting device mounted to the back side of the printed circuit board each for selectively illuminating one of the light channels;
wherein each of the light channels has an associated sealed light cavity, the sealed light cavity to prevent light from one of the at least two light emitting devices bleeding into another other light channel.
